(19) United States
(12) Patent Application Publication
(10) Pub. No.: US 2008/0239106 A1
(43) Pub. Date: Oct. 2, 2008

(54) REDUNDANT-BIT-ADDED DIGITAL-ANALOG CONVERTER, ANALOG-DIGITAL CONVERTER, AND IMAGE SENSOR

(75) Inventor: Takafumi SANO, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/055,706

(22) Filed: Mar. 26, 2008

(30) Foreign Application Priority Data
Mar. 27, 2007 (JP) 2007-080860

(51) Int. Cl. H04N 5/217; H03M 1/66; H03M 1/12

(52) U.S. Cl. 348/241; 341/144; 341/155; 348/E05.079

(57) ABSTRACT

A redundant-bit-added digital-analog converter has a first input terminal and a second input terminal and outputs a ramp voltage obtained by quantizing a voltage difference between a first voltage+ΔV and a second voltage−ΔV with n+1/2^{q} bits, when a voltage input to the first input terminal is the first voltage, a voltage input to the second input terminal is the second voltage, and ΔV=(first voltage-second voltage)/2^{q+1} (where n is a natural number of 3 or more and q is a natural number of n−2 or less).

### BACKGROUND

1. Technical Field

The present invention relates to a redundant-bit-added digital-analog converter converting a digital signal into an analog signal, an analog-digital converter using the digital-analog converter, and an image sensor using the analog-digital converter.

2. Related Art

A CMOS image sensor (hereinafter, referred to as “CMOS sensor”) is an image sensor employing logic processes, and can be mounted on a single chip with a peripheral driving circuit, an analog-digital (AD) converter, a signal processing circuit, and the like in addition to an image sensor. Particularly, the CMOS sensor mounted with the AD converter has attracted attention in the field of the camera design in that it is not necessary to design an analog circuit requiring a high SN ratio.

AD converters are classified into an integrating AD converter and a sequentially-comparing AD converter. The integrating AD converter is small in AD difference and can secure excellent linearity, but has a problem with a small conversion rate. The sequentially-comparing AD converter is advantageous in power consumption and conversion rate, but has a problem in that the area of capacitive elements increases with an increase in gradation (the number of bits).

In order to solve the above-mentioned problems, Japanese Patent No. 3507800 discloses a method using two types of integrating AD conversion circuits, in which bits are divided into higher bits and lower bits and the higher bits and the lower bits are quantized with the integrating AD conversion circuits, respectively.

However, in Japanese Patent No. 3507800, since the AD difference is small with high precision but the integrating AD conversion circuit is used twice in series, there is a problem in that the power consumption is great and the AD conversion rate cannot be enhanced.

In order to solve the above-mentioned problem, as shown in FIGS. 13 and 14, a method of converting m higher bits (where m is a natural number of 1 or more; m=2 in FIG. 13) with a sequentially-comparing type and converting n lower bits (where n is a natural number of 1 or more; n=3 in FIG. 13) with an integrating type is used to convert an analog signal Vs into a digital signal.

However, in the integrating AD conversion of the lower bits, when a DA conversion circuit (3-bit DAC) 107 has been subjected to an offset or when a comparison circuit (comparator) 120 has been subjected to a delay, as shown in FIG. 15, the waveform of a ramp voltage Vramp may be pushed up or down relative to an ideal waveform or the boundary between the higher bits and the lower bits may not be correctly converted in analog-to-digital conversion.

In order to solve the above-mentioned problem, as shown in FIGS. 9 and 10, a method of converting 3 lower bits in an integrating manner in total 12 steps by 0.25 bit (that is, two steps) above and below of 3 bits (that is, eight steps) using a 3.5-bit DAC 300 instead of the 3-bit DAC 107 is known.

However, the 3.5-bit DAC 300 is constructed as a resistor string type shown in FIG. 11 and a decoder 370 requires 12 4-input AND circuit as shown in FIG. 12. Since the 4-input AND circuit includes five NMOS transistors and five PMOS transistors, the decoder 370 requires total 120 transistors.

When 2 higher bits are converted in a sequentially-comparing AD conversion manner and 7 lower bits are converted in an integrating AD conversion manner, as shown in FIG. 2, a 7.5-bit DAC 400 is necessary and the 7.5-bit DAC 400 is constructed as a total 192-step resistor string type including 7-bit (that is, 128 steps) resistors R032 to R159, 0.25-bit (that is, 32 steps) resistors R160 to R191 in the upper portion, and 0.25-bit (that is, 32 steps) resistors R000 to R031 in the lower portion, as shown in FIG. 6.

In this case, as shown in FIG. 7, since the decoder 471 requires 192 8-input AND circuit (9 NMOS transistors and 9 PMOS transistors), the decoder uses total 3456 transistors. When the number of transistors increases, a chip area increases and the transistors serve as a noise source, thereby causing a decrease in SN ratio.

On the other hand, DA converters of types other than the resistor string type, such as a current type or charge-balance binary control type and an R-2R, are not suitable for the following reasons. The above-mentioned AD converter converts the higher bits in a sequentially-comparing AD conversion manner and converts the lower bits in an integrating AD conversion manner. In converting the higher bits, two voltages of an upper limit voltage VRP and a lower limit voltage VRN for determining an input range is used to perform the AD conversion. In converting the lower bits in the integrating AD conversion manner, a step-like waveform is generated between a range between VRP+ΔV and VRN−ΔV over the upper limit voltage VRP and the lower limit voltage VRN so as to enhance conversion precision in the boundary between the higher bits and the lower bits. For example, when 3 lower bits are converted in the AD conversion manner, a step-like waveform is generated by a 3.5-bit DA converter of total 12 steps including 8 steps between the upper limit voltage VRP and the lower limit voltage VRN and 2 steps of ΔV by adding a redundant bit of 0.5 bit.

In the current type DA converter, since a voltage is generated from current, a voltage of a type other than two of the upper limit voltage VRP and the lower limit voltage VRN is used. Then, the matching property of the higher bits and the lower bits is deteriorated and a lot of redundant bits need to be increased. The increase in redundant bits causes a decrease in conversion rate.

In the charge-balance binary control type or the R-2R, the decoder circuit is small. However, these types are advantageous in dividing the voltage difference between two voltages into 2-power steps and performing the DA conversion, but are disadvantageous in constructing a DA converter with bits other than an integer bit, such as 3.5 bits or 7.5 bits. A DA converter raised by 1 bit may be considered, but the voltage range thereof is too wide and thus the DA converter may not work. For example, when the voltage difference between the lower limit voltage VRN=0.6 V and the upper limit voltage VRP=2.2 V is converted in a 3-bit DA conversion manner with a voltage source of 3 bits and a 2-step DA conversion is performed to the outside of the voltage range (3.5-bit DA conversion), 1 LSB (Least Significant Bit: analog resolution)=0.2 V and the analog voltage range of the 3.5-bit DA converter is from 0.2 V to 2.6 V due to the redundant bit of 2 LSB. On the other hand, when a 4-bit DA converter is embodied, the analog voltage range is from −0.2 V to 3.0 V due to the redundant bit of 4 LSB and thus it cannot be embodied with a single voltage source of 3.0 V.

### SUMMARY

The invention is directed to provide a redundant-bit-added digital-analog converter having a small noise and a small circuit scale, an analog-digital converter using the digital-analog converter, and an image sensor using the analog-digital converter.

A redundant-bit-added digital-analog converter according to an aspect of the invention is a redundant-bit-added digital-analog converter having a first input terminal and a second input terminal and outputs a ramp voltage obtained by quantizing a voltage difference between a first voltage+ΔV and a second voltage−ΔV with n+1/2^{q} bits, when a voltage input to the first input terminal is the first voltage, a voltage input to the second input terminal is the second voltage, and ΔV=(first voltage-second voltage)/2^{q+1} (where n is a natural number of 3 or more and q is a natural number of n−2 or less). The digital-analog converter includes: a first active element of which the source terminal is connected to a first potential line; a second active element of which the source terminal is connected to a second potential line; k resistive elements (where k=2^{(q+1)}+2) connected in series between the drain terminal of the first active element and the drain terminal of the second active element; a first differential amplifier circuit having a first terminal connected to a connecting point between the first resistive element and the second resistive element connected to the drain terminal of the first active element, a second terminal connected to the second input terminal, and an output terminal connected to the gate terminal of the first active element; a second differential amplifier circuit having a first terminal connected to a connecting point between the k-th resistive element and the (k−1)-th resistive element connected to the drain terminal of the second active element, a second terminal connected to the first input terminal, and an output terminal connected to the gate terminal of the second active element; k switching elements including a first switching element connected between a terminal of the j-th resistive element (where j is any natural number satisfying 1≦j≦k) close to the first potential line and a first line so as to be switched to a connected state/disconnected state on the basis of a j-th control signal and a second switching element connected between a terminal of the j-th resistive element close to the second potential line and a second line so as to be switched to a connected state/disconnected state on the basis of a j-th control signal; (n−q−1)-bit binary control type digital-analog converter outputting a quantized voltage obtained by quantizing a voltage difference between the output voltage of a first buffer circuit connected to the first line and the output voltage of a second buffer circuit connected to the second line with (n−q−1) bits; a third buffer circuit receiving the quantized voltage and outputting the ramp voltage; and a decoder including k k/2-input logic circuits controlling the k switching circuits and the binary control type digital-analog converter on the basis of a clock signal.

In the redundant-bit-added digital-analog converter, the binary control type digital-analog converter may be a voltage-added R-2R ladder circuit.

According to the above-mentioned configuration, since the decoder can be constructed by the k k/2-input logic circuits (for example, k=2²+2=6 3-input logic circuits when q=1), it is possible to greatly reduce the circuit scale in comparison with the case where it is constructed by only the resistor string type, thereby reducing the noise.

An analog-digital converter according to another aspect of the invention includes: an analog signal line transmitting an analog signal; an upper limit voltage line transmitting an upper limit voltage of the analog signal; a lower limit voltage line transmitting a lower limit voltage of the analog signal; a ramp voltage line connected to the first input terminal of the redundant-bit-added digital-analog converter according to claim 1 or 2 and the upper limit voltage line and connected to the second input terminal and the lower limit voltage line so as to transmit the ramp voltage output from the redundant-bit-added digital-analog converter; a comparison circuit having a first terminal and a second terminal and outputting a comparison result signal as the comparison result of the voltage applied to the first terminal with the voltage applied to the second terminal from a comparison result output terminal; a reference voltage line connected to the first terminal so as to transmit a reference voltage for determining an operation voltage of the comparison circuit; a switching element connected between the second terminal and the comparison result output terminal and being in a connected state in a period of time when the analog signal is transmitted via the analog signal line; m capacitive elements of which the i-th capacitive element (where 1≦i≦m and m is a natural number of 1 or more) is set to a capacitance of 2^{m-i}×C (where C is a positive real number) and ends of which are connected in parallel to the second terminal; m switching circuits connected to the other ends of the m capacitive elements, respectively and being switched to be connectable to one of the analog signal line, the lower limit voltage line, and the upper limit voltage line; a second capacitive element set to a capacitance of C and having an end connected to the second terminal; a second switching circuit connected to the other end of the second capacitive element and being switched to be connectable to one of the analog signal line, the lower limit voltage line, and the ramp voltage line; a count line transmitting a count value obtained by counting the number of clocks from the start time of the clock signal; an m-bit latch circuit; an n-bit latch circuit; and a control circuit that is connected to the output line of the comparison result output terminal and the count line and that controls the m switching circuits on the basis of the comparison result signal, sequentially inputs the comparison result signal, which is output by sequentially connecting the upper limit voltage line to the m capacitive elements, to them-bit latch circuit, and inputs the count value to the n-bit latch circuit when the potential of the comparison result signal output by connecting the ramp voltage line to the second capacitive element is changed from a first potential to a second potential.

In the analog-digital converter, the control circuit may control the i-th switching circuit to return the potential of the i-th comparison result signal from the second potential to the first potential in a predetermined time after the potential of the i-th comparison result signal is changed from the first potential to the second potential.

An image sensor according to another aspect of the invention includes a plurality of photoelectric conversion elements and the above-mentioned analog-digital converter. Here, the voltage of the analog signal is a voltage obtained by photoelectrically converting the analog signal by the use of the plurality of photoelectric conversion elements.

According to the above-mentioned configuration, since the m higher bits can be converted in a sequentially-comparing AD conversion manner and the n lower bits can be converted in an integrating AD conversion manner, the power consumption is small, the AD difference is small with high precision, and the number of capacitive elements can be reduced in comparison with the configuration constructed by only the sequentially-comparing AD converter, thereby reducing the layout area. The quantized ramp voltage, which is obtained by giving a margin of 1/2 k bits to the n bits, is used to convert the n lower bits in an integrating AD conversion manner. Accordingly, even when an offset, etc. occurs in the DA conversion circuit generating the ramp voltage, an excellent AD conversion characteristic is obtained.

### BRIEF DESCRIPTION OF THE DRAWINGS

FIG. 1 is a circuit diagram illustrating a configuration of an image sensor according to an embodiment of the invention.

FIG. 2 is a circuit diagram illustrating a configuration of an analog-digital converter according to an embodiment of the invention.

FIG. 3 is a timing diagram illustrating an operation of the analog-digital converter.

FIG. 4 is a circuit diagram illustrating a configuration of a 7.5-bit digital-analog converter.

FIGS. 5A and 5B are circuit diagrams illustrating a configuration of a decoder of the 7.5-bit digital-analog converter.

FIG. 6 is a circuit diagram illustrating a configuration of a related 7.5-bit digital-analog converter.

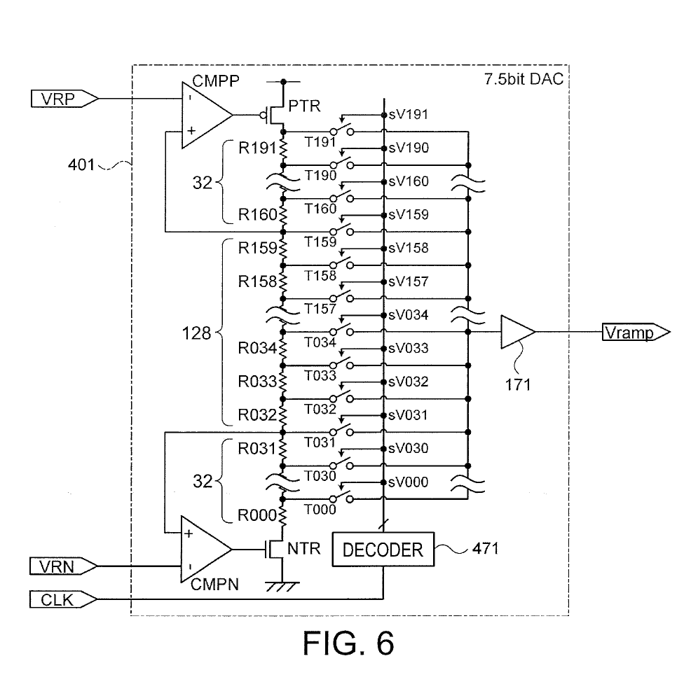

FIG. 7 is a circuit diagram illustrating a configuration of the related 7.5-bit digital-analog converter.

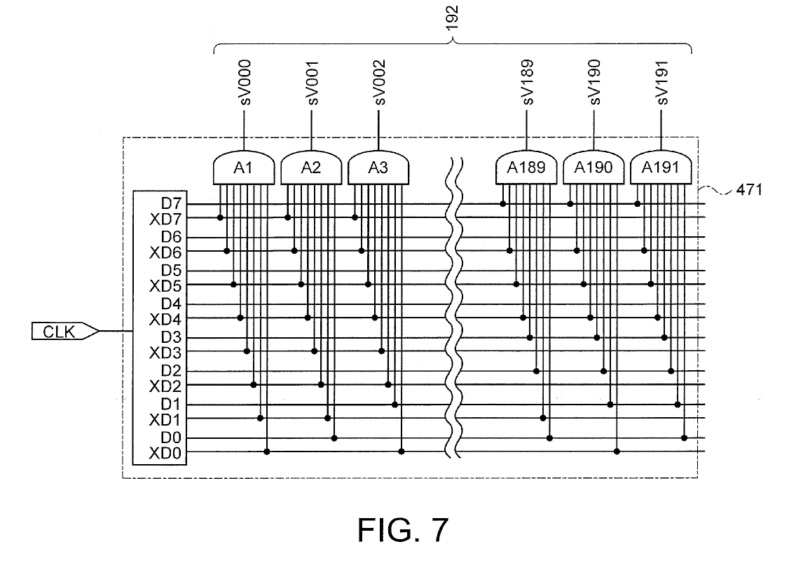

FIG. 8 is a circuit diagram illustrating a configuration of a 5-bit image sensor.

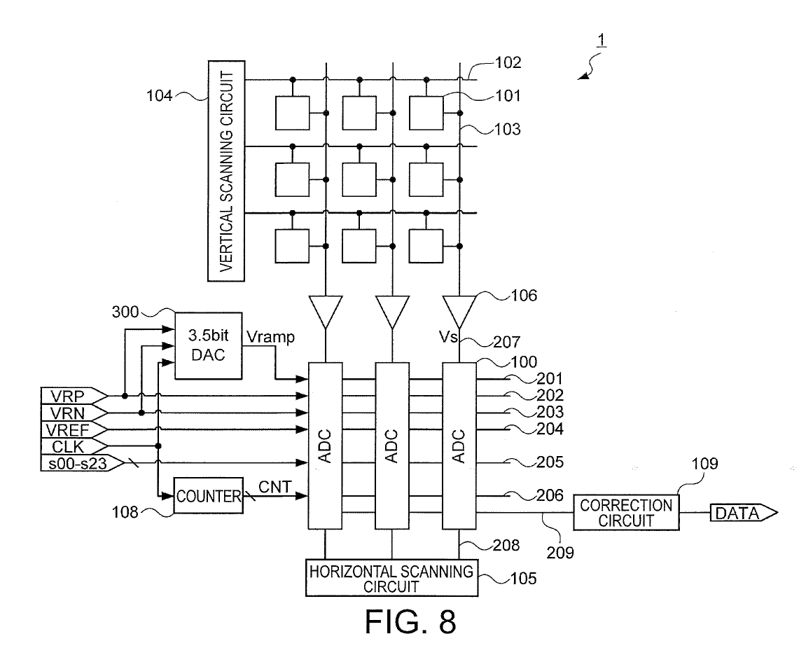

FIG. 9 is a circuit diagram illustrating a configuration of a 5-bit analog-digital converter.

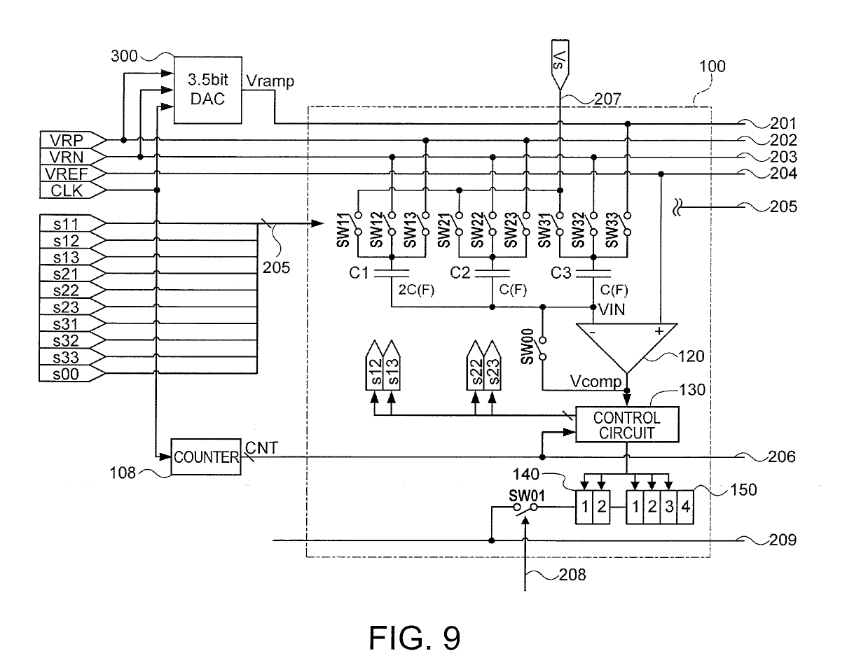

FIG. 10 is a timing diagram illustrating an operation of the 5-bit analog-digital converter.

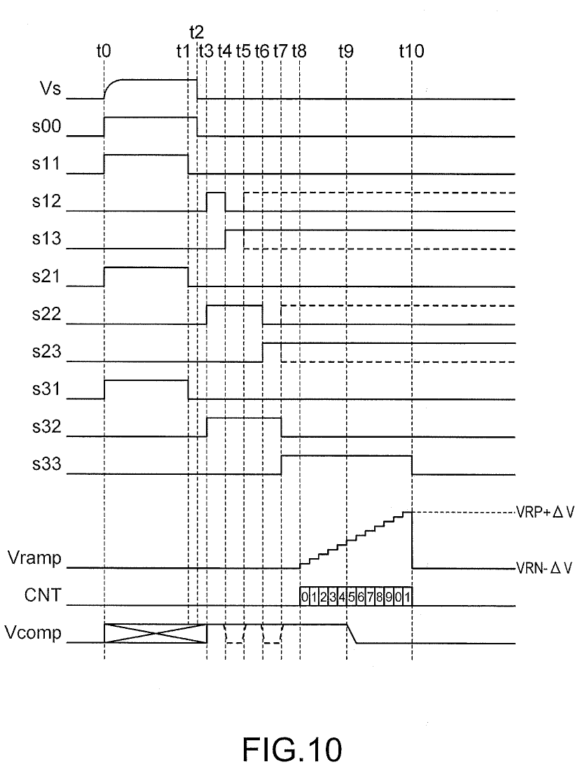

FIG. 11 is a circuit diagram illustrating a configuration of a 3.5-bit digital-analog converter.

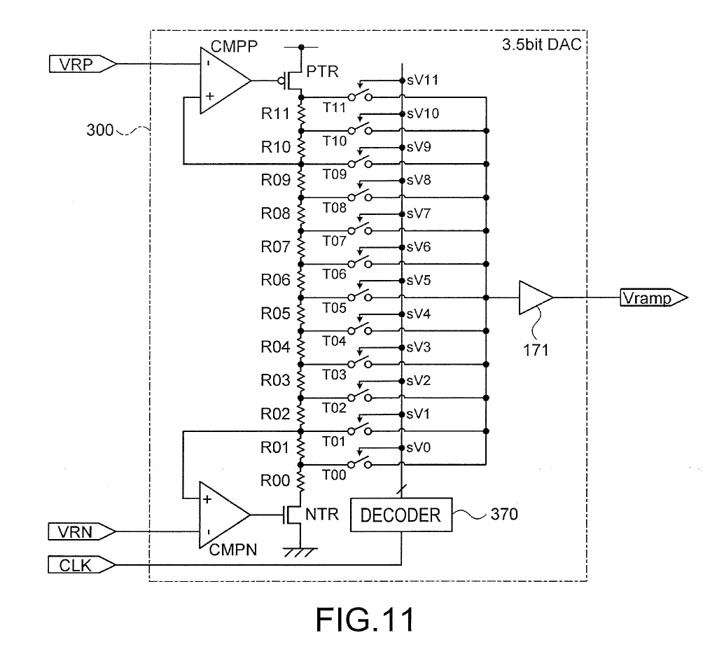

FIG. 12 is a circuit diagram illustrating a configuration of a decoder of the 3.5-bit digital-analog converter.

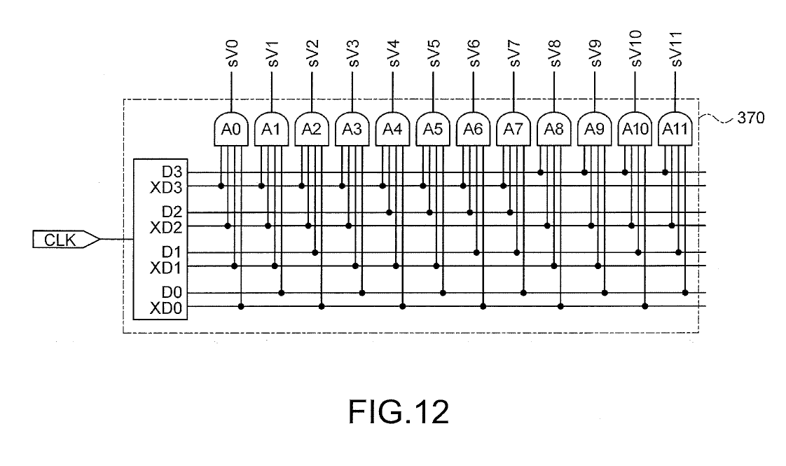

FIG. 13 is a circuit diagram illustrating a configuration of a related analog-digital converter.

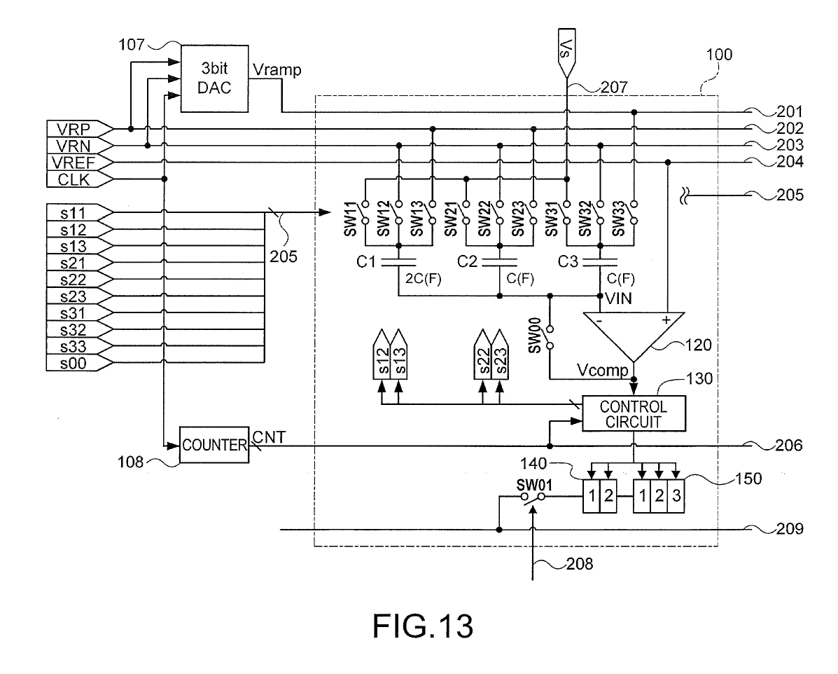

FIG. 14 is a timing diagram illustrating an operation of the related analog-digital converter.

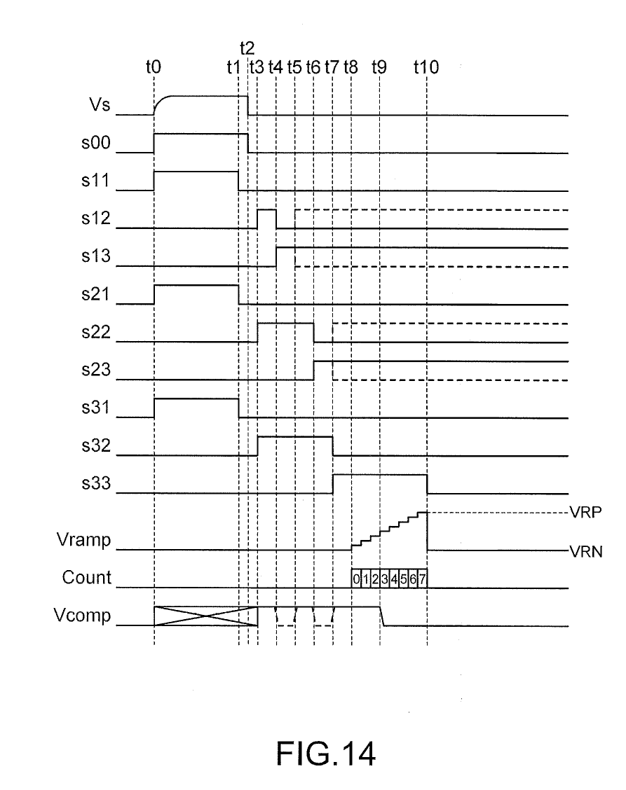

FIG. 15 is a graph illustrating a relation between a related ramp voltage and 2 higher bits.

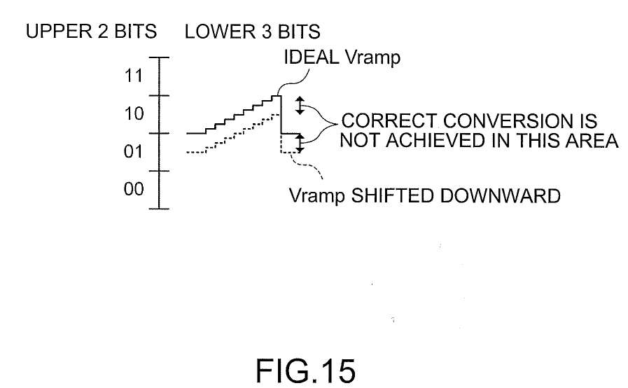

### DESCRIPTION OF EXEMPLARY EMBODIMENTS

Hereinafter, exemplary embodiments of the invention will be described with reference to the accompanying drawings.

### <Configuration of Image Sensor>

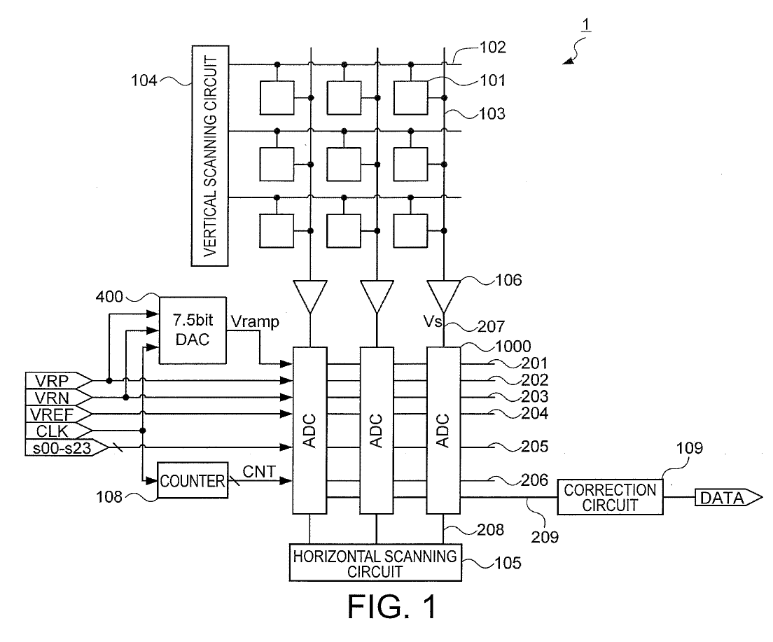

FIG. 1 is a circuit diagram illustrating a configuration of an image sensor according to an embodiment of the invention, where a 3×3 pixel image sensor is shown to simplify the description. It will be also described that an analog signal is converted into digital data with m=2 higher bits and n=7 lower bits. Here, an integrating AD conversion is performed on the basis of a ramp voltage obtained by quantizing a voltage difference between a lower limit voltage−ΔV and an upper limit voltage+ΔV with 7+1/2¹ bits (k=1)=7.5 bits on the basis of a clock signal, where q=1 and ΔV=(upper limit voltage−lower limit voltage)/2¹⁺¹=(upper limit voltage−lower limit voltage)/4.

As shown in FIG. 1, an image sensor 1 includes pixels 101 arranged in a 3×3 matrix, three vertical scanning lines 102, three horizontal scanning lines 103, a vertical scanning circuit 104, three buffers 106, three analog-digital converters (ADC) 1000, 7.5-bit digital-analog converter (DAC) 400, a counter 108, a horizontal scanning circuit 105, and a correction circuit 109.

The buffer 106 retains an analog signal Vs of the pixels 101 in a selected row and transmits the retained analog signal to an analog signal line 207.

The 7.5-bit DAC 400 transmits a ramp voltage Vramp, which is obtained by quantizing a voltage difference between the upper limit voltage VRP+ΔV and the lower limit voltage VRN−ΔV with 7.5 bits (that is, 192 clocks), to a ramp voltage line 201 on the basis of an upper limit voltage VRP and a lower limit voltage VRN of the analog signal Vs and a clock signal CLK. The upper limit voltage VRP is transmitted to an upper limit voltage line 202 and the lower limit voltage VRN is transmitted to a lower limit voltage line 203. A reference voltage VREF is transmitted to a reference voltage line 204.

The counter 108 transmits a 7.5-bit count value, which is obtained by counting the number of clocks from the start of the clock signal CLK, to eight count lines 206.

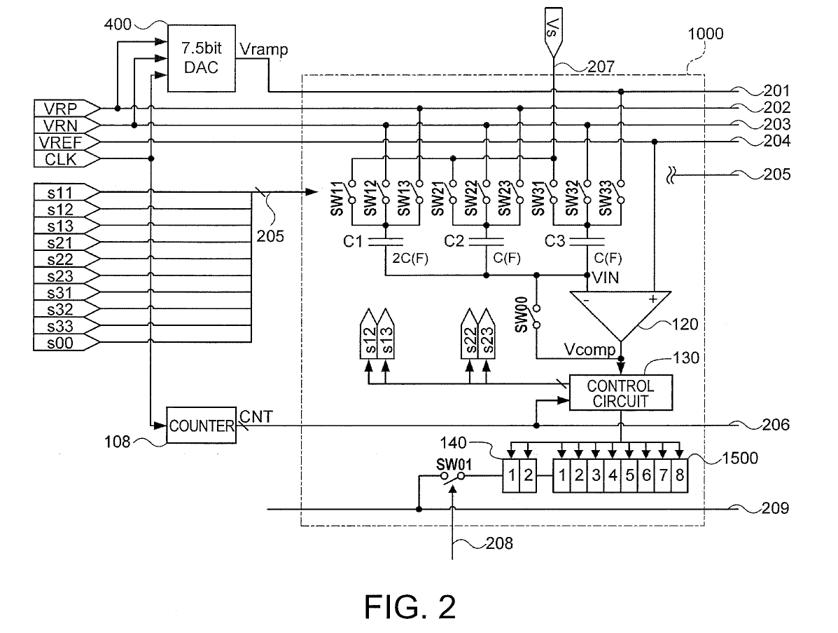

Control signals s00 to s23 for controlling a switching circuit to be described later with reference to FIG. 2 are transmitted to a control line 205.

Three ADCs 1000 are connected to the analog signal lines 207, respectively. The three ADCs 1000 are connected in common to the ramp voltage line 201, the upper limit voltage line 202, the lower limit voltage line 203, the reference voltage line 204, the control line 205, and the count line 206. The ADC 1000 converts the analog signal Vs into a digital signal with 2 higher bits and 7.5 lower bits and transmits the digital signal to a data output line 209 in accordance with a column selecting line 208 from the horizontal scanning circuit 105.

The correction circuit 109 corrects the digital signal transmitted from the data output line 209 and outputs the corrected digital signal.

### <Configuration of 7.5-Bit DAC>

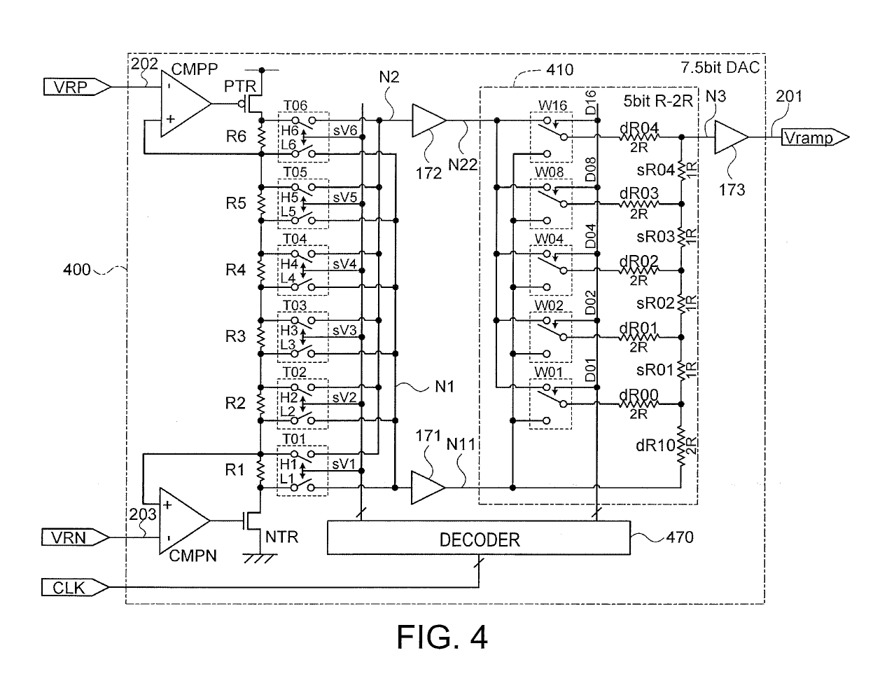

A configuration of the 7.5-bit digital-analog converter will be described now with reference to FIG. 4. FIG. 4 is a circuit diagram illustrating the configuration of the 7.5-bit digital-analog converter.

As shown in FIG. 4, the 7.5-bit DAC 400 includes an Nch transistor NTR as the first active element, a Pch transistor PTR as the second active element, six (k=2⁽¹⁺¹⁾+2 because of q=1) resistors R1 to R6, an operational amplifier CMPN as the first differential amplifier circuit, an operation amplifier CMPP as the second differential amplifier circuit, six switching circuits T01 to T06, a decoder 470, a buffer 171 as the first buffer circuit, a buffer 172 as the second buffer circuit, a buffer 173 as the third buffer circuit, and a voltage-added R-2R ladder circuit (hereinafter, referred to as “5-bit R-2R circuit”) 410 as the 5-bit binary control type digital-analog converter.

The Nch transistor NTR, the resistors R1 to R6, and the Pch transistor PTR are connected in series between the ground potential as the first potential line and the source potential as the second potential line.

A positive (+) terminal as the first terminal of the operational amplifier CMPP is connected to a connection point between the resistors R5 and R6, a negative (−) terminal as the second terminal is connected to the upper limit voltage line 202, and an output terminal thereof is connected to the gate terminal of the Pch transistor PTR.

A positive (+) terminal of the operational amplifier CMPN is connected to a connection point between the resistors R1 and R2, a negative (−) terminal thereof is connected to the lower limit voltage line 203, and an output terminal thereof is connected to the gate terminal of the Nch transistor NTR.

The switching circuit T01 includes a switch L1 as the first switching element and a switch H1 as the second switching element. The switch L1 is connected between a connection point between the drain terminal of the Nch transistor NTR and the resistor R1 and a line N1 as the first line and is switched to a connected state/disconnected state in response to a first control signal sV1 from the decoder 470. The switch H1 is connected between a connection point between the resistor R1 and the resistor R2 and a line N2 as the second line and is switched to a connected state/disconnected state in response to the first control signal sV1 from the decoder 470.

The switching circuit T02 includes a switch L2 as the first switching element and a switch H2 as the second switching element. The switch L2 is connected between a connection point between the resistor R1 and the resistor R2 and the line N1 and is switched to a connected state/disconnected state in response to a second control signal sV2 from the decoder 470. The switch H2 is connected between a connection point between the resistor R2 and the resistor R3 and the line N2 and is switched to a connected state/disconnected state in response to the second control signal sV2 from the decoder 470.

The switching circuit T03 includes a switch L3 as the first switching element and a switch H3 as the second switching element. The switch L3 is connected between a connection point between the resistor R2 and the resistor R3 and the line N1 and is switched to a connected state/disconnected state in response to a third control signal sV3 from the decoder 470. The switch H3 is connected between a connection point between the resistor R3 and the resistor R4 and the line N2 and is switched to a connected state/disconnected state in response to the third control signal sV3 from the decoder 470.

The switching circuit T04 includes a switch L4 as the first switching element and a switch H4 as the second switching element. The switch L4 is connected between a connection point between the resistor R3 and the resistor R4 and the line N1 and is switched to a connected state/disconnected state in response to a fourth control signal sV4 from the decoder 470. The switch H4 is connected between a connection point between the resistor R4 and the resistor R5 and the line N2 and is switched to a connected state/disconnected state in response to the fourth control signal sV4 from the decoder 470.

The switching circuit T05 includes a switch L5 as the first switching element and a switch H5 as the second switching element. The switch L5 is connected between a connection point between the resistor R4 and the resistor R5 and the line N1 and is switched to a connected state/disconnected state in response to a fifth control signal sV5 from the decoder 470. The switch H5 is connected between a connection point between the resistor R5 and the resistor R6 and the line N2 and is switched to a connected state/disconnected state in response to the fifth control signal sV5 from the decoder 470.

The switching circuit T06 includes a switch L6 as the first switching element and a switch H6 as the second switching element. The switch L6 is connected between a connection point between the resistor R5 and the resistor R6 and the line N1 and is switched to a connected state/disconnected state in response to a sixth control signal sV6 from the decoder 470. The switch H6 is connected between a connection point between the resistor R6 and the drain terminal of the Pch transistor PTR and the line N2 and is switched to a connected state/disconnected state in response to the sixth control signal sV6 from the decoder 470.

An input terminal of the buffer 171 is connected to the line N1 and an output terminal thereof is connected to the line N11. An input terminal of the buffer 172 is connected to the line N2 and an output terminal thereof is connected to the line N22.

### <Configuration of 5-Bit-R-2R Circuit>

The 5-bit R-2R circuit 410 is connected to the line N11 and the line N22 and outputs a quantized voltage, which is obtained by quantizing a voltage difference between the output voltage of the buffer 171 and the output voltage of the buffer 172 with 5 bits (that is, 32 steps), to the line N3. An input terminal of the buffer 173 is connected to the line N3 and an output terminal thereof is connected to the ramp voltage line 201.

The 5-bit R-2R circuit 410 includes five switching circuits W01, W02, W04, W08, and W16, resistors sR01, sR02, sR03, and sR04 having a resistance of R (Ω), and resistors dR00, dR01, dR02, dR03, dR04, and dR10 having a resistance of 2R (Ω).

The switching circuit W01 is switched to be connected to the line N22 when a control signal D01 from the decoder 470 has an H level and to be connected to the line N11 when the control signal has an L level. The output terminal thereof is connected to an end of the resistor dR00.

The switching circuit W02 is switched to be connected to the line N22 when a control signal D02 from the decoder 470 has an H level and to be connected to the line N11 when the control signal has an L level. The output terminal thereof is connected to an end of the resistor dR01.

The switching circuit W04 is switched to be connected to the line N22 when a control signal D04 from the decoder 470 has an H level and to be connected to the line N11 when the control signal has an L level. The output terminal thereof is connected to an end of the resistor dR02.

The switching circuit W08 is switched to be connected to the line N22 when a control signal D08 from the decoder 470 has an H level and to be connected to the line N11 when the control signal has an L level. The output terminal thereof is connected to an end of the resistor dR03.

The switching circuit W16 is switched to be connected to the line N22 when a control signal D16 from the decoder 470 has an H level and to be connected to the line N11 when the control signal has an L level. The output terminal thereof is connected to an end of the resistor dR04.

The resistor dR10 is connected between the line N11 and the other end of the resistor dR00. The resistor sR01 is connected between the other end of the resistor dR00 and the other end of the resistor dR01. The resistor sR02 is connected between the other end of the resistor dR01 and the other end of the resistor dR02. The resistor sR03 is connected between the other end of the resistor dR02 and the other end of the resistor dR03. The resistor sR04 is connected between the other end of the resistor dR03 and the line N3.

### <Configuration of Decoder>

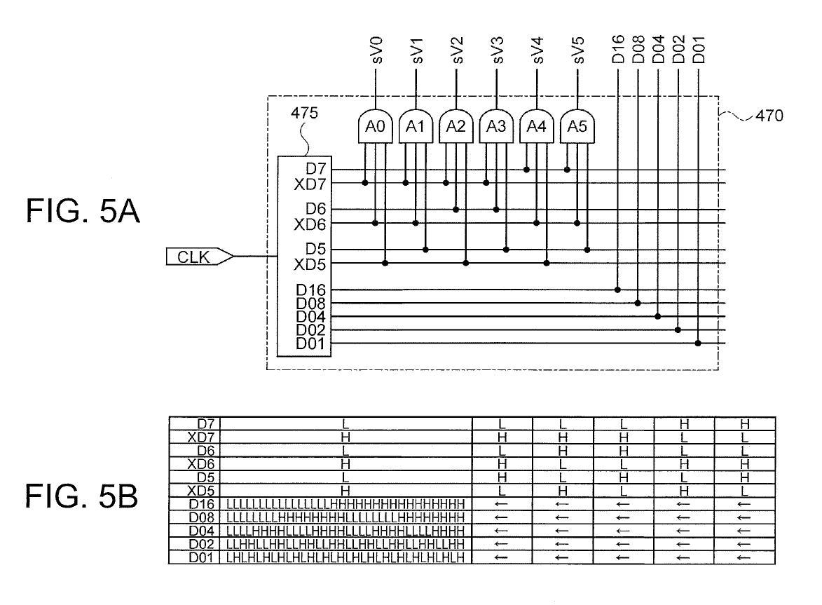

A configuration of the decoder of the 7.5-bit digital-analog converter will be described now with reference to FIG. 5. FIG. 5 is a circuit diagram illustrating the configuration of the decoder of the 7.5-bit digital-analog converter.

As shown in FIG. 5A, the decoder 470 includes a selection circuit 475 outputting selection signals D5, XD5, D6, XD6, D7, and XD7 and control signals D01, D02, D04, D08, and D16 in response to the clock signal CLK and six 3-input logic circuits (AND circuits) A0 to A5.

The AND circuit A0 receives the selection signals XD5, XD6, and XD7 and outputs the control signal sV0. The AND circuit A1 receives the selection signals D5, XD6, and XD7 and outputs the control signal sV1. The AND circuit A2 receives the selection signals XD5, D6, and XD7 and outputs the control signal sV2. The AND circuit A3 receives the selection signals D5, D6, and XD7 and outputs the control signal sV3. The AND circuit A4 receives the selection signals XD5, XD6, and D7 and outputs the control signal sV4. The AND circuit A5 receives the selection signals D5, XD6, and D7 and outputs the control signal sV5.

As shown in FIG. 5B, the selection circuit 475 outputs the selection signals D5, XD5, D6, XD6, D7, and XD7 and the control signals D01, D02, D04, D08, and D16 in 192 combinations in response to the clock signal CLK.

### <Configuration of ADC>

A configuration of the analog-digital converter will be described now with reference to FIG. 2. FIG. 2 is a circuit diagram illustrating the configuration of the analog-digital converter.

As shown in FIG. 2, the ADC 1000 includes a comparator 120 as the comparison circuit, a control circuit 130, a switch SW00 as the switching element, a capacitor C1 as the first capacitive element, a capacitor C2 as the second capacitive element, a capacitor C3 as the second capacitive element, switches SW11, SW12, and SW13 constituting a first switching circuit, switches SW21, SW22, and SW23 constituting a second switching circuit, switches SW31, SW32, and SW33 constituting a second switching circuit, a 2-bit latch circuit 140, and an 8-bit latch circuit 1500.

The comparator 120 includes a positive (+) terminal as the first terminal, a negative (−) terminal as the second terminal, and a comparison result output terminal. When the voltage of the positive terminal>the voltage of the negative terminal, a comparison result signal Vcomp output from the comparison result output terminal has the positive largest voltage. When the voltage of the positive terminal<the voltage of the negative terminal, the comparison result signal Vcomp has the negative largest voltage. The positive terminal is connected to the reference voltage line 204 and is supplied with the reference voltage VREF.

The switch SW00 is connected between the negative terminal and the comparison result output terminal of the comparator 120. The switch SW00 is in a connected state when the control signal s00 has an H level and is in a disconnected state when the control signal has an L level.

The capacitor C1 is set to a capacitance of 2²⁻¹×C (where is any capacitance)=2C (F), the capacitor C2 is set to a capacitance of 2²⁻²×C=C (F), and the capacitor C3 is set to a capacitance of C (F). The ends of the capacitors C1 to C3 are connected to the negative terminal of the comparator 120.

The switch SW11 is connected between the other end of the capacitor C1 and the analog signal line 207. The switch SW12 is connected between the other end of the capacitor C1 and the lower limit voltage line 203. The switch SW13 is connected between the other end of the capacitor C1 and the upper limit voltage line 202. The switch SW11 is in a connected state when the control signal s11 has an H level and is in a disconnected state when the control signal has an L level. The switch SW12 is in a connected state when the control signal s12 has an H level and is in a disconnected state when the control signal has an L level. The switch SW13 is in a connected state when the control signal s13 has an H level and is in a disconnected state when the control signal has an L level.

The switch SW21 is connected between the other end of the capacitor C2 and the analog signal line 207. The switch SW22 is connected between the other end of the capacitor C2 and the lower limit voltage line 203. The switch SW23 is connected between the other end of the capacitor C2 and the upper limit voltage line 202. The switch SW21 is in a connected state when the control signal s21 has an H level and is in a disconnected state when the control signal has an L level. The switch SW22 is in a connected state when the control signal s22 has an H level and is in a disconnected state when the control signal has an L level. The switch SW23 is in a connected state when the control signal s23 has an H level and is in a disconnected state when the control signal has an L level.

The switch SW31 is connected between the other end of the capacitor C3 and the analog signal line 207. The switch SW32 is connected between the other end of the capacitor C3 and the lower limit voltage line 203. The switch SW33 is connected between the other end of the capacitor C3 and the ramp voltage line 201. The switch SW31 is in a connected state when the control signal s31 has an H level and is in a disconnected state when the control signal has an L level. The switch SW32 is in a connected state when the control signal s32 has an H level and is in a disconnected state when the control signal has an L level. The switch SW33 is in a connected state when the control signal s33 has an H level and is in a disconnected state when the control signal has an L level.

The control circuit 130 is connected to the comparison result output terminal of the comparator 120 and three count lines 206.

The control circuit 130 transmits the comparison result signal Vcomp to the first bit of the latch circuit 140 in the period of time for the AD conversion of the first higher bit and switches the control signal s12 to the H level and the control signal s13 to the L level when the comparison result signal Vcomp is changed from the positive largest voltage to the negative largest voltage.

The control circuit 130 transmits the comparison result signal Vcomp to the second bit of the latch circuit 140 in the period of time for the AD conversion of the second higher bit and switches the control signal s22 to the H level and the control signal s23 to the L level when the comparison result signal Vcomp is changed from the positive largest voltage to the negative largest voltage.

The control circuit 130 transmits a 7-bit count value CNT to the latch circuit 1500 when the comparison result signal Vcomp is changed from the positive largest voltage to the negative largest voltage in the period of time for the AD conversion of 7 lower bits.

### <Operation of ADC>

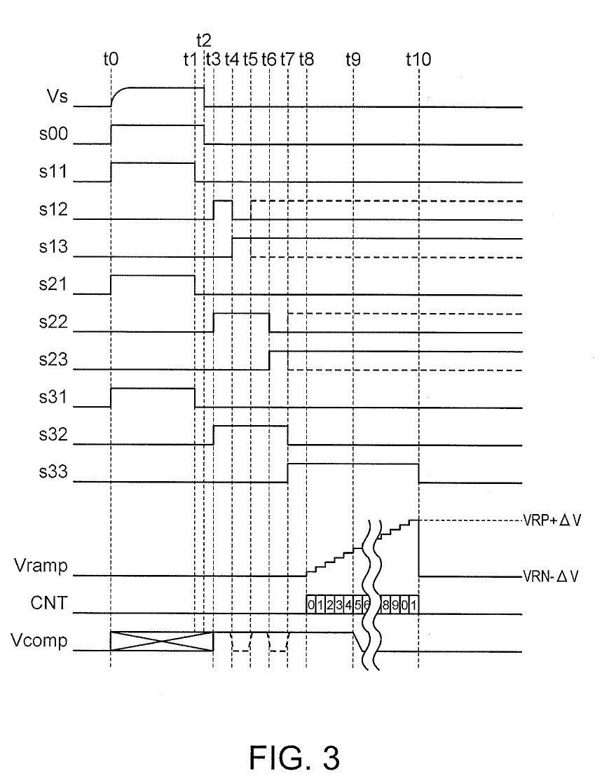

An operation of the analog-digital converter will be described with reference to FIG. 3. FIG. 3 is a timing diagram illustrating the operation of the analog-digital converter.

First, in the period from time t0 to time t2, by changing the control signal s00 to the H level to allow the switch SW00 to be in the connected state, the comparison result output terminal and the negative terminal of the comparator 120 are short-circuited and the voltage VIN of the negative terminal (that is, the ends of the capacitors C1 to C3) becomes the reference voltage VREF. In this state, when the control signals s11, s21, and s31 are changed to the H level, the switches SW11, SW21, and SW31 are in the connected state and the analog signal Vs is thus transmitted to the other ends of the capacitors C1 to C3. Charges of Q1=2C(Vs−VREF) are accumulated in the capacitor C1, charges of Q2=C(Vs−VREF) are accumulated in the capacitor C2, and charges of Q3=C(Vs−VREF) are accumulated in the capacitor C3. That is, the charges of Q=Q1+Q2+Q3=4C(Vs−VREF) in total are accumulated in the capacitors C1 to C3.

At time t1, by changing the control signals s11, s21, and s31 to the L level, the switches SW11, SW21, and SW31 become the disconnected state and the charges of the capacitors C1 to C3 are retained therein. At time t2, by changing the control signal s00 to the L level, the switch SW00 becomes in the disconnected state, the current path is intercepted, and thus the charges of the capacitors C1 to C3 are retained.

At time t3, by changing the control signals s12, s22, and s32 to the H level, the switches SW12, SW22, and SW32 become the connected state and the lower limit voltage VRN is applied to the other ends of the capacitors C1 to C3. By the law of conservation of electric charge, the charges of the capacitors C1 to C3 are Q=4C(Vs−VREF)=4C(VRN−VIN) and the voltage of the negative terminal is VIN=VREF+VRN−Vs. Since the relation of the lower limit voltage VRN<the analog signal Vs is established, the voltage VREF of the positive terminal of the comparator 120>the voltage VIN of the negative voltage and thus the comparison result signal Vcomp has the positive largest voltage.

At time t4, by changing the control signal s12 to the L level and changing the control signal s13 to the H level, the switch SW12 becomes the disconnected state and the switch SW13 becomes the connected state. Accordingly, the upper limit voltage VRP is applied to the other end of the capacitor C1. The charges of the capacitors C1 to C3 are Q=4C (Vs−VREF)=2C (VRP−VIN)+2C (VRN−VIN) and the voltage of the negative terminal is VIN=VREF+((VRP+VRN)/2)−Vs. That is, the comparator 120 sequentially compares whether the analog signal Vs is larger than (VRP+VRN)/2, whereby the first higher bit of the analog signal Vs is obtained.

When the analog signal Vs>(VRP+VRN)/2, the comparison result signal Vcomp has the positive largest voltage and the control circuit 130 inputs the H level to the first bit of the latch circuit 140.

On the other hand, when the analog signal Vs<(VRP+VRN)/2, the comparison result signal Vcomp has the negative largest voltage. Then, the control circuit 130 inputs the L level to the first bit of the latch circuit 140 and changes the control signal s12 and the control signal s13 to the H level and the L level, respectively to return the comparison result signal Vcomp to the positive largest voltage at time t5, as indicated by a dotted line in FIG. 3.

At time t6, by changing the control signal s22 and the control signal s23 to the L level and the H level, respectively, the switch SW22 becomes the disconnected state and the switch SW23 becomes the connected state. Accordingly, the upper limit voltage VRP is applied to the other end of the capacitor C2.

### <When the First Bit is at the H Level>

When the first bit of the latch circuit 140 is at the H level, the charges of the capacitors C1 to C3 are Q=4C(Vs−VREF)=3C(VRP−VIN)+C(VRN−VIN) and the voltage of the negative terminal is VIN=VREF+(VRP×3/4+VRN/4)−Vs. That is, the comparator 120 sequentially compares whether the analog signal Vs is larger than (VRP×3/4+VRN/4), whereby the second higher bit of the analog signal Vs is obtained.

When the analog signal Vs>(VRP×3/4+VRN/4), the comparison result signal Vcomp has the positive largest voltage and the control circuit 130 inputs the H level to the second bit of the latch circuit 140.

On the other hand, when the analog signal Vs<(VRP×3/4+VRN/4), the comparison result signal Vcomp has the negative largest voltage. Then, the control circuit 130 inputs the L level to the second bit of the latch circuit 140 and changes the control signal s22 and the control signal s23 to the H level and the L level, respectively to return the comparison result signal Vcomp to the positive largest voltage at time t7, as indicated by a dotted line in FIG. 3.

### <When the First Bit is at the L Level>

When the first bit of the latch circuit 140 is at the L level, the charges of the capacitors C1 to C3 are Q=4C(Vs−VREF)=3C(VRN−VIN)+C(VRP−VIN) and the voltage of the negative terminal is VIN=VREF+(VRP/4+VRN×3/4)−Vs. That is, the comparator 120 sequentially compares whether the analog signal Vs is larger than (VRP/4+VRN×3/4), whereby the second higher bit of the analog signal Vs is obtained.

When the analog signal Vs>(VRP/4+VRN×3/4), the comparison result signal Vcomp has the positive largest voltage and the control circuit 130 inputs the H level to the second bit of the latch circuit 140.

On the other hand, when the analog signal Vs<(VRP/4+VRN×3/4), the comparison result signal Vcomp has the negative largest voltage. Then, the control circuit 130 inputs the L level to the second bit of the latch circuit 140 and changes the control signal s22 and the control signal s23 to the H level and the L level, respectively to return the comparison result signal Vcomp to the positive largest voltage at time t7.

At time t7, by changing the control signal s32 and the control signal s33 to the L level and the H level, respectively, the switch SW32 becomes the disconnected state and the switch SW33 becomes the connected state. Accordingly, the ramp voltage Vramp is applied to the other end of the capacitor C3. At time t8, by starting the clock signal CLK, the ramp voltage Vramp is generated by the 7.5-bit DAC 400. The counter 108 starts counting the clocks from 0 at the time of starting the clock signal CLK.

### <When the First Bit=H and the Second Bit=H>

When the first bit of the latch circuit 140 is at the H level and the second bit is at the H level, the charges of the capacitors C1 to C3 are Q=4C(Vs−VREF)=3C(VRP−VIN)+C(Vramp−VIN) and the voltage of the negative terminal is VIN=VREF+(VRP×3/4+Vramp/4)−Vs. That is, the comparator 120 compares at the point at which the analog signal Vs>(VRP×3/4+Vramp/4) in an integrating manner, whereby 3 lower bits of the analog signal Vs are obtained.

### <When the First Bit=H and the Second Bit=L>

When the first bit of the latch circuit 140 is at the H level and the second bit is at the L level, the charges of the capacitors C1 to C3 are Q=4C(Vs−VREF)=2C(VRP−VIN)+C(VRN−VIN)+C(Vramp−VIN) and the voltage of the negative terminal is VIN=VREF+(VRP/2+VRN/4+Vramp/4)−Vs. That is, the comparator 120 compares at the point at which the analog signal Vs>(VRP/2+VRN/4+Vramp/4) in an integrating manner, whereby 7 lower bits of the analog signal Vs are obtained.

### <When the First Bit=L and the Second Bit=H>

When the first bit of the latch circuit 140 is at the L level and the second bit is at the H level, the charges of the capacitors C1 to C3 are Q=4C(Vs−VREF)=2C(VRN−VIN)+C(VRP−VIN)+C(Vramp−VIN) and the voltage of the negative terminal is VIN=VREF+(VRN/2+VRP/4+Vramp/4)−Vs. That is, the comparator 120 compares at the point at which the analog signal Vs>(VRN/2+VRP/4+Vramp/4) in an integrating manner, whereby 7 lower bits of the analog signal Vs are obtained.

### <When the First Bit=L and the Second Bit=L>

When the first bit of the latch circuit 140 is at the L level and the second bit is at the L level, the charges of the capacitors C1 to C3 are Q=4C(Vs−VREF)=3C(VRN−VIN)+C(Vramp−VIN) and the voltage of the negative terminal is VIN=VREF+(VRP×3/4+Vramp/4)−Vs. That is, the comparator 120 compares at the point at which the analog signal Vs>(VRP×3/4+Vramp/4) in an integrating manner, whereby 7 lower bits of the analog signal Vs are obtained.

In this embodiment, it is described that the comparison result signal Vcomp is changed from the positive largest voltage to the negative largest voltage at the sixth clock (the count value of which is 5) at time t9. The control circuit 130 inputs the count value of CNT=5 (0000101 in the septimal system) to the latch circuit 1500.

The correction circuit 109 corrects data so as to add the value of the most significant bit of the lower bits to the 2 higher bits when the lower bits are 8 bits.

As described above, the 2 higher bits of the analog signal Vs can be converted into digital data in a sequentially-comparing manner and the 7 lower bits can be converted into digital data in an integrating manner.

According to the above-mentioned embodiment, it is possible to obtain the following advantages.

In this embodiment, since the m higher bits can be converted into digital data in a sequentially-comparing AD conversion manner and the n lower bits can be converted into digital data in an integrating AD conversion manner, the power consumption is small, the AD difference is small with high precision, and the number of capacitive elements can be reduced in comparison with the configuration including only the sequentially-comparing AD converter, thereby reducing the layout area. The quantized ramp voltage, which is obtained by giving a margin of 1/2^{k} bits to the n bits, is used to convert the n lower bits in an integrating AD conversion manner. Accordingly, even when an offset, etc. occurs in the DA conversion circuit generating the ramp voltage, an excellent AD conversion characteristic is obtained. Since the decoder can be constructed by k k/2-input logic circuits (for example, k=2²+2=6 3-input logic circuits when q=1), it is possible to greatly reduce the circuit scale in comparison with the case where it is constructed only by the resistor string, thereby reducing the noise.

Although the embodiments of the invention have been described, the invention is limited to the embodiment, but may be modified in various forms without departing from the gist of the invention. Hereinafter, modified examples of the invention will be described.

### MODIFIED EXAMPLE 1

Modified Example 1 of the image sensor according to the invention will be described. It has been described in the above-mentioned embodiment that the analog signal Vs is converted to digital data with 2 higher bits and 7 lower bits. However, for example, when the analog signal is converted into digital data with 3 higher bits and 7 lower bits, the first capacitor is set to 2³⁻¹C pF=4C pF, the second capacitor is set to 2³⁻²C pF=2C pF, the third capacitor is set to 2³⁻³C pF=C pF, a 5-bit DAC is constructed instead of the 3-bit DAC 107, and a 3-bit latch circuit and a 7-bit latch circuit are provided.

### MODIFIED EXAMPLE 2

Modified Example 2 of the image sensor according to the invention will be described. Although the image sensor has been described in the above-mentioned embodiment, the invention may be applied to the AD conversion using a line sensor in which plural sensors are arranged in a columnar manner.

### MODIFIED EXAMPLE 3

Modified Example 3 of the image sensor according to the invention will be described. In the above-mentioned embodiment, it has been described that the 192-step ramp voltage Vramp from the 7.5-bit DAC 400 is used. However, the clock signal may be controlled to stop at 161 clocks as long as the integrating AD conversion can be performed well with the 161-th-step ramp voltage Vramp.

The entire disclosure of Japanese Patent Application No. 2007-080860, filed Mar. 27, 2007, is incorporated by reference herein.

1. A redundant-bit-added digital-analog converter having a first input terminal and a second input terminal and outputting a ramp voltage obtained by quantizing a voltage difference between a first voltage+ΔV and a second voltage−ΔV with n+1/2^{q} bits, when a voltage input to the first input terminal is the first voltage, a voltage input to the second input terminal is the second voltage, and ΔV=(first voltage-second voltage)/2^{q+1} (where n is a natural number of 3 or more and q is a natural number of n−2 or less), the digital-analog converter comprising:
a first active element of which the source terminal is connected to a first potential line;
a second active element of which the source terminal is connected to a second potential line;
k resistive elements (where k=2^{(q+1)}+2) connected in series between the drain terminal of the first active element and the drain terminal of the second active element;
a first differential amplifier circuit having a first terminal connected to a connecting point between the first resistive element and the second resistive element connected to the drain terminal of the first active element, a second terminal connected to the second input terminal, and an output terminal connected to the gate terminal of the first active element;
a second differential amplifier circuit having a first terminal connected to a connecting point between the k-th resistive element and the (k−1)-th resistive element connected to the drain terminal of the second active element, a second terminal connected to the first input terminal, and an output terminal connected to the gate terminal of the second active element;
k switching elements including a first switching element connected between a terminal of the j-th resistive element (where j is any natural number satisfying 1≦j≦k) close to the first potential line and a first line so as to be switched to a connected state/disconnected state on the basis of a j-th control signal and a second switching element connected between a terminal of the j-th resistive element close to the second potential line and a second line so as to be switched to a connected state/disconnected state on the basis of a j-th control signal;
(n−q−1)-bit binary control type digital-analog converter outputting a quantized voltage obtained by quantizing a voltage difference between the output voltage of a first buffer circuit connected to the first line and the output voltage of a second buffer circuit connected to the second line with (n−q−1) bits;
a third buffer circuit receiving the quantized voltage and outputting the ramp voltage; and
a decoder including k k/2-input logic circuits controlling the k switching circuits and the binary control type digital-analog converter on the basis of a clock signal.

2. The redundant-bit-added digital-analog converter according to claim 1, wherein the binary control type digital-analog converter is a voltage-added R-2R ladder circuit.

3. An analog-digital converter comprising:
an analog signal line transmitting an analog signal;
an upper limit voltage line transmitting an upper limit voltage of the analog signal;
a lower limit voltage line transmitting a lower limit voltage of the analog signal;
a ramp voltage line connected to the first input terminal of the redundant-bit-added digital-analog converter according to claim 1 and the upper limit voltage line and connected to the second input terminal and the lower limit voltage line so as to transmit the ramp voltage output from the redundant-bit-added digital-analog converter;
a comparison circuit having a first terminal and a second terminal and outputting a comparison result signal as the comparison result of the voltage applied to the first terminal with the voltage applied to the second terminal from a comparison result output terminal;
a reference voltage line connected to the first terminal so as to transmit a reference voltage for determining an operation voltage of the comparison circuit;
a switching element connected between the second terminal and the comparison result output terminal and being in a connected state in a period of time when the analog signal is transmitted via the analog signal line;
m capacitive elements of which the i-th capacitive element (where 1≦i≦m and m is a natural number of 1 or more) is set to a capacitance of 2^{m-i}×C (where C is a positive real number) and ends of which are connected in parallel to the second terminal;
m switching circuits connected to the other ends of the m capacitive elements, respectively and being switched to be connectable to one of the analog signal line, the lower limit voltage line, and the upper limit voltage line;
a second capacitive element set to a capacitance of C and having an end connected to the second terminal;
a second switching circuit connected to the other end of the second capacitive element and being switched to be connectable to one of the analog signal line, the lower limit voltage line, and the ramp voltage line;
a count line transmitting a count value obtained by counting the number of clocks from the start time of the clock signal;
an m-bit latch circuit;
an (n+1)-bit latch circuit; and
a control circuit that is connected to the output line of the comparison result output terminal and the count line and that controls the m switching circuits on the basis of the comparison result signal, sequentially inputs the comparison result signal, which is output by sequentially connecting the upper limit voltage line to the m capacitive elements, to the m-bit latch circuit, and inputs the count value to the (n+1)-bit latch circuit when the potential of the comparison result signal output by connecting the ramp voltage line to the second capacitive element is changed from a first potential to a second potential.

4. The analog-digital converter according to claim 3, wherein the control circuit controls the i-th switching circuit to return the potential of the i-th comparison result signal from the second potential to the first potential in a predetermined time after the potential of the i-th comparison result signal is changed from the first potential to the second potential.

5. An image sensor having a plurality of photoelectric conversion elements and an analog-digital converter,
wherein the analog-digital converter comprises:
an analog signal line transmitting an analog signal;
an upper limit voltage line transmitting an upper limit voltage of the analog signal;
a lower limit voltage line transmitting a lower limit voltage of the analog signal;
a ramp voltage line connected to the first input terminal of the redundant-bit-added digital-analog converter according to claim 1 and the upper limit voltage line and connected to the second input terminal and the lower limit voltage line so as to transmit the ramp voltage output from the redundant-bit-added digital-analog converter;
a comparison circuit having a first terminal and a second terminal and outputting a comparison result signal as the comparison result of the voltage applied to the first terminal with the voltage applied to the second terminal from a comparison result output terminal;
a reference voltage line connected to the first terminal so as to transmit a reference voltage for determining an operation voltage of the comparison circuit;
a switching element connected between the second terminal and the comparison result output terminal and being in a connected state in a period of time when the analog signal is transmitted via the analog signal line;
m capacitive elements of which the i-th capacitive element (where 1≦i≦m and m is a natural number of 1 or more) is set to a capacitance of 2^{m-i}×C (where C is a positive real number) and ends of which are connected in parallel to the second terminal;
m switching circuits connected to the other ends of the m capacitive elements, respectively and being switched to be connectable to one of the analog signal line, the lower limit voltage line, and the upper limit voltage line;
a second capacitive element set to a capacitance of C and having an end connected to the second terminal;
a second switching circuit connected to the other end of the second capacitive element and being switched to be connectable to one of the analog signal line, the lower limit voltage line, and the ramp voltage line;
a count line transmitting a count value obtained by counting the number of clocks from the start time of the clock signal;
an m-bit latch circuit;
an (n+1)-bit latch circuit; and
a control circuit that is connected to the output line of the comparison result output terminal and the count line and that controls the m switching circuits on the basis of the comparison result signal, sequentially inputs the comparison result signal, which is output by sequentially connecting the upper limit voltage line to the m capacitive elements, to the m-bit latch circuit, and inputs the count value to the (n+1)-bit latch circuit when the potential of the comparison result signal output by connecting the ramp voltage line to the second capacitive element is changed from a first potential to a second potential, and
wherein the voltage of the analog signal is a voltage obtained by photoelectrically converting the analog signal by the use of the photoelectric conversion elements.

6. The image sensor according to claim 5, wherein the control circuit controls the i-th switching circuit to return the potential of the i-th comparison result signal from the second potential to the first potential in a predetermined time after the potential of the i-th comparison result signal is changed from the first potential to the second potential.

7. An analog-digital converter comprising:
an analog signal line transmitting an analog signal;
an upper limit voltage line transmitting an upper limit voltage of the analog signal;
a lower limit voltage line transmitting a lower limit voltage of the analog signal;
a ramp voltage line connected to the first input terminal of the redundant-bit-added digital-analog converter according to claim 2 and the upper limit voltage line and connected to the second input terminal and the lower limit voltage line so as to transmit the ramp voltage output from the redundant-bit-added digital-analog converter;
a comparison circuit having a first terminal and a second terminal and outputting a comparison result signal as the comparison result of the voltage applied to the first terminal with the voltage applied to the second terminal from a comparison result output terminal;
a reference voltage line connected to the first terminal so as to transmit a reference voltage for determining an operation voltage of the comparison circuit;
a switching element connected between the second terminal and the comparison result output terminal and being in a connected state in a period of time when the analog signal is transmitted via the analog signal line;
m capacitive elements of which the i-th capacitive element (where 1≦i≦m and m is a natural number of 1 or more) is set to a capacitance of 2^{m-i}×C (where C is a positive real number) and ends of which are connected in parallel to the second terminal;
m switching circuits connected to the other ends of the m capacitive elements, respectively and being switched to be connectable to one of the analog signal line, the lower limit voltage line, and the upper limit voltage line;
a second capacitive element set to a capacitance of C and having an end connected to the second terminal;
a second switching circuit connected to the other end of the second capacitive element and being switched to be connectable to one of the analog signal line, the lower limit voltage line, and the ramp voltage line;
a count line transmitting a count value obtained by counting the number of clocks from the start time of the clock signal;
an m-bit latch circuit;
an (n+1)-bit latch circuit; and
a control circuit that is connected to the output line of the comparison result output terminal and the count line and that controls the m switching circuits on the basis of the comparison result signal, sequentially inputs the comparison result signal, which is output by sequentially connecting the upper limit voltage line to the m capacitive elements, to the m-bit latch circuit, and inputs the count value to the (n+1)-bit latch circuit when the potential of the comparison result signal output by connecting the ramp voltage line to the second capacitive element is changed from a first potential to a second potential.

8. An image sensor having a plurality of photoelectric conversion elements and an analog-digital converter,
wherein the analog-digital converter comprises:
an analog signal line transmitting an analog signal;
an upper limit voltage line transmitting an upper limit voltage of the analog signal;
a lower limit voltage line transmitting a lower limit voltage of the analog signal;
a ramp voltage line connected to the first input terminal of the redundant-bit-added digital-analog converter according to claim 2 and the upper limit voltage line and connected to the second input terminal and the lower limit voltage line so as to transmit the ramp voltage output from the redundant-bit-added digital-analog converter;
a comparison circuit having a first terminal and a second terminal and outputting a comparison result signal as the comparison result of the voltage applied to the first terminal with the voltage applied to the second terminal from a comparison result output terminal;
a reference voltage line connected to the first terminal so as to transmit a reference voltage for determining an operation voltage of the comparison circuit;
a switching element connected between the second terminal and the comparison result output terminal and being in a connected state in a period of time when the analog signal is transmitted via the analog signal line;
m capacitive elements of which the i-th capacitive element (where 1≦i≦m and m is a natural number of 1 or more) is set to a capacitance of 2^{m-i}×C (where C is a positive real number) and ends of which are connected in parallel to the second terminal;
m switching circuits connected to the other ends of the m capacitive elements, respectively and being switched to be connectable to one of the analog signal line, the lower limit voltage line, and the upper limit voltage line;
a second capacitive element set to a capacitance of C and having an end connected to the second terminal;
a second switching circuit connected to the other end of the second capacitive element and being switched to be connectable to one of the analog signal line, the lower limit voltage line, and the ramp voltage line;
a count line transmitting a count value obtained by counting the number of clocks from the start time of the clock signal;
an m-bit latch circuit;
an (n+1)-bit latch circuit; and
a control circuit that is connected to the output line of the comparison result output terminal and the count line and that controls the m switching circuits on the basis of the comparison result signal, sequentially inputs the comparison result signal, which is output by sequentially connecting the upper limit voltage line to the m capacitive elements, to the m-bit latch circuit, and inputs the count value to the (n+1)-bit latch circuit when the potential of the comparison result signal output by connecting the ramp voltage line to the second capacitive element is changed from a first potential to a second potential, and
wherein the voltage of the analog signal is a voltage obtained by photoelectrically converting the analog signal by the use of the photoelectric conversion elements.
